(19) United States
(12) Patent Application Publication
(10) Pub. No.: US 2024/0222217 A1
(43) Pub. Date: Jul. 4, 2024

(54) SEMICONDUCTOR PACKAGE INCLUDING HIGH THERMAL CONDUCTIVITY LAYER

(71) Applicant: Samsung Electronics Co., Ltd., Suwon-si (KR)

(72) Inventors: Sunjae KIM, Seoul (KR); Eunsil KANG, Suwon-si (KR); Daehyun KIM, Seoul (KR); Sunkyoung SEO, Cheonan-si (KR)

(73) Assignee: Samsung Electronics Co., Ltd., Suwon-si (KR)

(21) Appl. No.: 18/593,381

(22) Filed: Mar. 1, 2024

Related U.S. Application Data
(63) Continuation of application No. 17/332,471, filed on May 27, 2021, now Pat. No. 11,948,851.

(30) Foreign Application Priority Data
Nov. 30, 2020 (KR) 10-2020-0163646

(51) Int. Cl. H01L 23/31; H01L 23/00; H01L 23/29; H01L 23/498; H01L 25/065; H01L 25/18; H01L 21/56

(52) U.S. Cl. CPC H01L 23/3192; H01L 23/295; H01L 23/3128; H01L 23/3185; H01L 23/49827; H01L 24/16; H01L 24/17; H01L 24/73; H01L 24/94; H01L 24/97; H01L 25/0657; H01L 25/18; H01L 21/561; H01L 24/02; H01L 24/05; H01L 24/13; H01L 2224/02331; H01L 2224/02372; H01L 2224/02381; H01L 2224/0557; H01L 2224/06519; H01L 2224/13024; H01L 2224/16145; H01L 2224/16146; H01L 2224/16235; H01L 2224/17181; H01L 2224/17519; H01L 2224/2929; H01L 2224/29386; H01L 2224/29499; H01L 2224/73204; H01L 2225/06513; H01L 2225/06541; H01L 2225/06568; H01L 2225/06589; H01L 2924/181; H01L 2924/1815; H01L 2924/18161

(57) ABSTRACT

A semiconductor package includes a first semiconductor chip on a wiring structure, a plurality of internal terminals between the wiring structure and the first semiconductor chip; a high thermal conductivity layer is between the wiring structure and the first semiconductor chip; and an encapsulator on the high thermal conductivity layer and contacting the second semiconductor chip. Sidewalls of at least the wiring structure and the encapsulator are substantially coplanar.

### CROSS-REFERENCE TO THE RELATED APPLICATIONS

This non-provisional patent application is a Continuation of U.S. application Ser. No. 17/332,471, filed on May 27, 2021, which claims priority from Korean Patent Application No. 10-2020-0163646, filed on Nov. 30, 2020, in the Korean Intellectual Property Office, the disclosure of which is incorporated herein by reference in its entirety.

### BACKGROUND 1. Field

The example embodiments of the disclosure relate to a semiconductor package including a high thermal conductivity layer and a formation method thereof.

### 2. Description of the Related Art

To cope with lightness, thinness, simplification, and miniaturization demands for electronic systems, research on various semiconductor packages capable of mounting a plurality of semiconductor chips is being conducted. Each of the plurality of semiconductor chips may generate heat of a higher temperature than a surrounding environment. Heat generated from the plurality of semiconductor chips may cause malfunctions in the electronic system and/or adversely affect the lifespan of the electronic system.

### SUMMARY

Some example embodiments of the disclosure provide a semiconductor package having efficient heat dissipation characteristics and a formation method thereof.

A semiconductor package according to some example embodiments of the disclosure includes a wiring structure; a first semiconductor chip on the wiring structure; a plurality of internal terminals is between the wiring structure and the first semiconductor chip; a high thermal conductivity layer between the wiring structure and the first semiconductor chip; and an encapsulator on the high thermal conductivity layer and contacting the second semiconductor chip. Sidewalls of at least the wiring structure and the encapsulator are substantially coplanar.

A semiconductor package according to some example embodiments of the disclosure includes a wiring structure including an active region and a plurality of scribe lanes in continuity with side surfaces of the active region; a semiconductor chip is on the wiring structure; a plurality of internal terminals between the wiring structure and the semiconductor chip; a high thermal conductivity layer between the wiring structure and the semiconductor chip and contacting the active region and the plurality of scribe lanes; and an encapsulator on the wiring structure and the high thermal conductivity layer and contacting the semiconductor chip is provided.

A semiconductor package according to some example embodiments of the disclosure includes a wiring structure; a semiconductor chip on the wiring structure; a plurality of internal terminals between the wiring structure and the semiconductor chip; a high thermal conductivity layer between the wiring structure and the semiconductor chip and an encapsulator on the high thermal conductivity layer and contacting the semiconductor chip. Sidewalls of at least the wiring structure and the encapsulator are substantially coplanar. An uppermost end of the high thermal conductivity layer is at a higher level than a lowermost end of the semiconductor chip. The uppermost end of the high thermal conductivity layer is at a lower level than an uppermost end of the semiconductor chip. The high thermal conductivity layer directly contacts a side surface of the semiconductor chip. The maximum contact height between the high thermal conductivity layer and the semiconductor chip is a first length. The thickness of the semiconductor chip is a second length. The first length is greater than half of the second length.

### BRIEF DESCRIPTION OF THE DRAWINGS

FIGS. 1 to 8 are sectional views of a semiconductor package according to some embodiments of the disclosure.

FIGS. 9, 10, 11, 14 and 19 are sectional views of a formation method for a semiconductor package according to some embodiments of the disclosure.

FIGS. 12 and 13 are views showing a portion of FIG. 11.

FIGS. 15 to 18 are views showing a portion of FIG. 14.

### DETAILED DESCRIPTION OF EXEMPLARY EMBODIMENTS

One or more example embodiments will be described in detail with reference to the accompanying drawings. Example embodiments, however, may be embodied in various different forms, and should not be construed as being limited to only the illustrated embodiments. Unless otherwise noted, like reference characters denote like elements throughout the attached drawings and written description, and thus descriptions will not be repeated.

Although the terms “first,” “second,” “third,” etc., may be used herein to describe various elements, components, regions, layers, and/or sections, these elements, components, regions, layers, and/or sections, should not be limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

Spatially relative terms, such as “below,” “above,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

When the terms “about” or “substantially” are used in this specification in connection with a numerical value, it is intended that the associated numerical value includes a manufacturing tolerance (e.g., ±10%) around the stated numerical value. Moreover, when the words “similar” and “substantially” are used in connection with composition and/or geometric shapes, it is intended that precision of composition and/or the geometric shape is not required but that latitude for the composition and/or shape is within the scope of the disclosure. It will be understood that these values, compositions, and shapes should be construed as including a manufacturing or operational tolerance (e.g., ±10%) around the stated numerical values, compositions, or shapes.

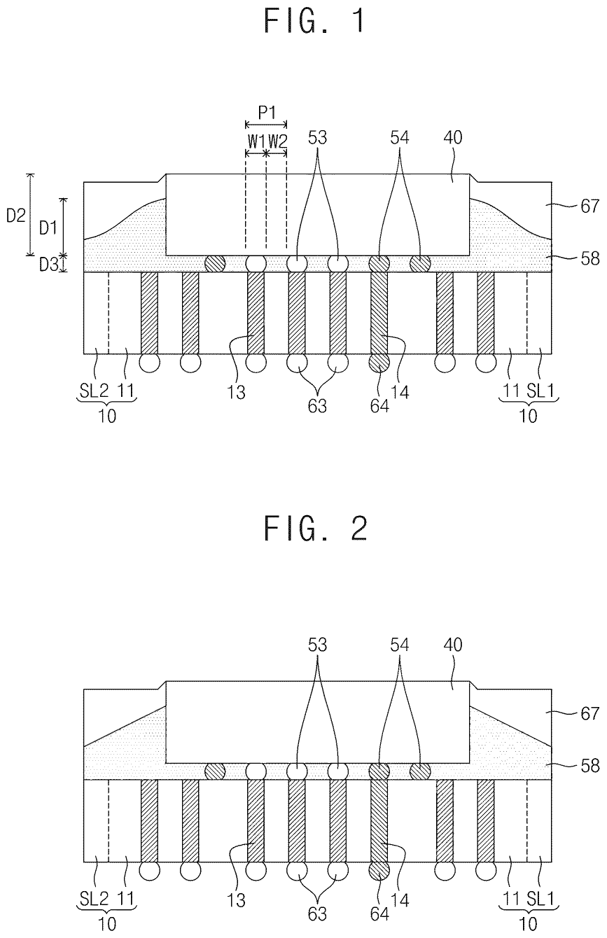

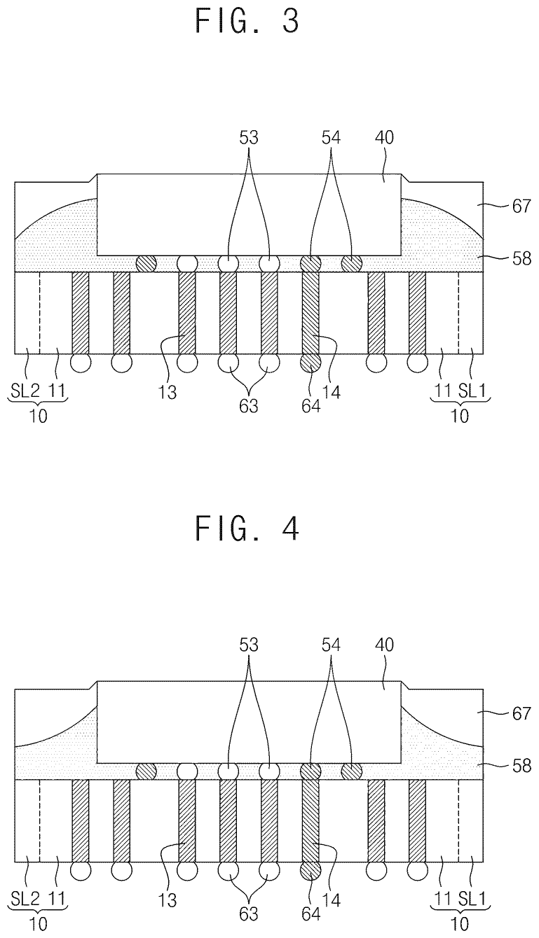

FIGS. 1 to 8 are sectional views of a semiconductor package according to some embodiments of the disclosure.

Referring to FIG. 1, the semiconductor package according to some embodiments may include a wiring structure 10, a first semiconductor chip 40, a plurality of first internal terminals 53, a plurality of internal heat dispersion terminals 54, a first high thermal conductivity layer 58, a plurality of external terminals 63, at least one external heat dispersion terminal 64, and an encapsulator 67.

In some embodiments, the wiring structure 10 maybe and/or include a semiconductor chip (not illustrated) such as a logic chip, a buffer chip, a controller chip, an application processor chip, an interposer chip, a volatile memory chip, a non-volatile memory chip, and/or a combination thereof. The wiring structure 10 mayinclude a printed circuit board, an interposer substrate, the semiconductor chip, and/or a combination thereof. For convenience of description, the following description will be given in conjunction with the case in which the wiring structure 10 is a logic chip.

In some embodiments, the first semiconductor chip 40 maybe and/or include a memory chip, a logic chip, a buffer chip, a controller chip, an application processor chip, an interposer chip, and/or a combination thereof. For example, the first semiconductor chip 40 mayinclude a volatile memory chip, a non-volatile memory chip, and/or a combination thereof. For convenience of description, the following description will be given in conjunction with the case in which the first semiconductor chip 40 is a memory chip.

The wiring structure 10 mayinclude an active region 11 and a plurality of scribe lanes SL1 and SL2. For example, the plurality of scribe lanes may include a first scribe lane SL1 and a second scribe lane SL2. The plurality of scribe lanes SL1 and SL2 may be in continuity with side surfaces of the active region 11, respectively. For example, the first scribe lane SL1 and the second scribe land SL2 may each be in contact with and/or define a respective edge of the active region 11. The active region 11 maybe disposed between the plurality of scribe lanes SL1 and SL2. In some embodiments, the active region 11 and the plurality of scribe lanes SL1 and SL2 may include a semiconductor layer such as a monocrystalline silicon layer.

A plurality of first through electrodes 13 and at least one first heat dispersion through electrode 14 maybe disposed in the active region 11. The plurality of first through electrodes 13 and the at least one first heat dispersion through electrode 14 maybe spaced apart from one another. Each of the plurality of first through electrodes 13 and the at least one first heat dispersion through electrode 14 mayextend vertically through the active region 11. The plurality of first through electrodes 13 and the at least one first heat dispersion through electrode 14 mayinclude a conductive material such as a metal (e.g., Cu, W, Ni, Co, Al, Ti, Ta, Ag, Pt, Au, Ru, Cr, Sn, and/or a combination thereof); a conductive oxide; a conductive nitride (e.g., WN, TiN, TaN, and/or a combination thereof); and/or a combination thereof. The conductive material may be electrically and/or thermally conductive. The at least one first heat dispersion through electrode 14 mayinclude a material substantially identical to that of the plurality of first through electrodes 13. For example, the at least one first heat dispersion through electrode 14 maybe formed at substantially the same time and/or under the same conditions as the plurality of first through electrodes 13. The at least one first heat dispersion through electrode 14 mayhave substantially the same size as each of the plurality of first through electrodes 13. In some embodiments, the at least one first heat dispersion through electrode 14 maybe omitted.

The plurality of external terminals 63 and the at least one external heat dispersion terminal 64 maybe disposed on a lower surface of the active region 11. Each of the plurality of external terminals 63 maybe electrically connected to a corresponding one of the plurality of first through electrodes 13. The at least one external heat dispersion terminal 64 maybe electrically connected to the at least one first heat dispersion through electrode 14.

The plurality of external terminals 63 mayinclude a conductive material such as a metal (e.g., Sn, Ag, Cu, W, Ni, Co, Al, Ti, Ta, Pt, Au, Ru, Cr, and/or a combination thereof); a conductive oxide; a conductive nitride (e.g., WN, TiN, TaN, and/or a combination thereof); and/or a combination thereof. Each of the plurality of external terminals 63 mayinclude a conductive bump, a conductive post, a conductive pin, a conductive pillar, a solder ball, and/or a combination thereof. The at least one external heat dispersion terminal 64 mayinclude a configuration similar to that of each of the plurality of external terminals 63. In some embodiments, the at least one external heat dispersion terminal 64 mayinclude a material substantially identical to that of the plurality of external terminals 63. For example, the at least one external heat dispersion terminal 64 maybe formed at substantially the same time and/or under the same conditions as the plurality of external terminals 63. The at least one external heat dispersion terminal 64 mayhave substantially the same size as each of the plurality of external terminals 63. In some embodiments, the at least one external heat dispersion terminal 64 maybe omitted, for example in the example embodiments wherein the at least one first heat dispersion through electrode 14 is omitted.

The first semiconductor chip 40 maybe disposed on the wiring structure 10. The horizontal width of the first semiconductor chip 40 maybe smaller than the horizontal width of the wiring structure 10. The plurality of first internal terminals 53 and the plurality of first internal heat dispersion terminals 54 maybe disposed between the first semiconductor chip 40 and the wiring structure 10. A portion of the first high terminal conductivity layer 58 maybe disposed between the wiring structure 10 and the first semiconductor chip 40. A portion of the first high thermal conductivity layer 58 maycover an upper surface of the wiring structure 10. The first high thermal conductivity layer 58 maypartially cover side surfaces of the first semiconductor chip 40. Each of the plurality of first internal terminals 53 and the plurality of first internal heat dispersion terminals 54 mayextend through the first high thermal conductivity layer 50 and, as such, may contact the wiring structure 10 and/or the first semiconductor chip 40.

The plurality of first internal terminals 53 mayinclude a conductive material such as a metal (e.g., Sn, Ag, Cu, W, Ni, Co, Al, Ti, Ta, Pt, Au, Ru, Cr, and/or a combination thereof); a conductive oxide; a conductive nitride (e.g., WN, TiN, TaN, and/or a combination thereof); and/or a combination thereof. Each of the plurality of first internal terminals 53 mayinclude a conductive bump, a conductive post, a conductive pin, a conductive pillar, a solder ball, and/or a combination thereof. Each of the plurality of first internal terminals 53 maybe connected to a corresponding one of the plurality of first through electrodes 13.

The plurality of first internal terminals 53 maybe disposed to have a first pitch P1. The maximum horizontal width of each of the plurality of first internal terminals 53 maybe a first width W1. In some embodiments, the first width W1 may be a width (e.g., an average and/or a representative) of the first internal terminal 53 at the center of the first internal terminal 53, and/or may correspond to the largest diameter of the first internal terminal 53. The minimum distance between the first internal terminals 53 maybe a second width W2. For example, the second width W2 may be a distance (e.g., an average and/or a representative) between neighboring edges of a first internal terminal 53 and a neighboring internal terminal 53. The first pitch P1 may correspond to the sum of the first width W1 and the second width W2. For example, the first pitch P1 may be about 1 to 80 μm. In some embodiments, the first pitch P1 may be about 10 to 25 μm.

Each of the plurality of first internal heat dispersion terminals 54 mayinclude a configuration similar to that of each of the plurality of first internal terminals 53. In some embodiments, each of the plurality of first internal heat dispersion terminals 54 mayinclude a material substantially identical to that of the plurality of first internal terminals 53, and/or may have been formed at substantially the same time and/or under the substantially the same conditions as the plurality of first internal terminals 53. Each of the plurality of first internal heat dispersion terminals 54 maybe spaced apart from the plurality of first internal terminals 53. Each of the plurality of first internal heat dispersion terminals 54 mayhave substantially the same size as each of the plurality of first internal terminals 53. The plurality of first internal heat dispersion terminals 54 and the plurality of first internal terminals 53 maybe disposed to have the first pitch P1. In some embodiments, at least one of the plurality of first internal heat dispersion terminals 54 maybe connected to the at least one first heat dispersion through electrode 14.

The thermal conductivity of the first high thermal conductivity layer 58 maybe 1 W/mK or more. In some embodiments, the thermal conductivity of the first high thermal conductivity layer 58 maybe about 1 to 5 W/mK. The first high thermal conductivity layer 58 mayinclude an underfill and/or a liquid encapsulant including a filler and a resin. The filler may include a material having high thermal conductivity. For example, the filler may be and/or include a spherical filler; the spherical filler may increase the flowability of the resin. The filler may include aluminum oxide (Al₂O₃), aluminum nitride (AlN), boron nitride (BN), silicon oxide (SiO₂), and/or a combination thereof. The spherical filler included in the filler may have a diameter of 0.1 to 10 μm. The diameter of the spherical filler may be selected on the basis of process efficiency. The diameter of the spherical filler may be selected, for example, on the basis of the minimum distance between the wiring structure 10 and the first semiconductor chip 40 and/or flowability of the filler. In some embodiments, the spherical filler may have a diameter of about 0.7 to 3 μm.

In some embodiments, for example when the filler includes the aluminum oxide (Al₂O₃), a low α-ray emission grade aluminum oxide (e.g., emission rate: 0.01 CPH/cm²) exhibiting low α-ray emission may be used. The aluminum oxide (Al₂O₃) may include an alpha (α) phase, a gamma (γ) phase, a polycrystal, and/or a combination thereof. The resin may include liquid crystalline epoxy resins (LCERs) including, as a backbone structure, multi-aromatics such as biphenyl, naphthyl, anthracenyl, etc. enabling mesogen pi-pi (π-π) stacking thereof. For example, in some embodiments the resin may include YX-4000(K) and/or YX-4000H(K) of Japan Epoxy Resins Company, for biphenyl, and/or may include HP4032D, HP4032SS, etc. of DIC Company, for naphthyl. In some embodiments, the concentration of multi-aromatics in the liquid crystalline epoxy resins (LCERs) may be determined such that the resin is thermally conductive but would not cause an electrical short, for example, in the wiring structure 10.

The high thermal conductivity layer 58 maybe between the wiring structure 10 and the first semiconductor chip 40, and/or may extend onto side surfaces of the first semiconductor chip 40. In some embodiments, the first high thermal conductivity layer 58 maycompletely cover one surface of the wiring structure 10. For example, the first high thermal conductivity layer 58 maycompletely cover an upper surface of the wiring structure 10. The first high thermal conductivity layer 58 maycompletely cover a surface (e.g., an upper surface) of the active region 11 and the plurality of scribe lanes SL1 and SL2. The first high thermal conductivity layer 58 maydirectly contact the active region 11 and the plurality of scribe lanes SL1 and SL2.

An uppermost end of the first high thermal conductivity layer 58 maybe formed at a higher level than a lowermost end of the first semiconductor chip 40. The first high thermal conductivity layer 58 maydirectly contact at least a portion of the side surfaces of the first semiconductor chip 40. For example, the maximum contact height between each side surface of the first semiconductor chip 40 and the first high thermal conductivity layer 58 maybe a first length D1. The thickness of the first semiconductor chip 40 maybe a second length D2. In some embodiments, the first length D1 may be greater than half of the second length D2. The uppermost end of the first high thermal conductivity layer 58 maybe formed at a lower level than an uppermost end of the first semiconductor chip 40. An upper surface of the first high thermal conductivity layer 58 mayhave various profiles. The upper surface of the first high thermal conductivity layer 58 mayinclude an inclined surface. In some embodiments, the upper surface of the first high thermal conductivity layer 58 maybe formed with a level gradually lowering with increasing distance from the first semiconductor chip 40.

The minimum distance between the wiring structure 10 and the first semiconductor chip 40 maybe a third length D3. The third length D3 may be 1 to 50 μm. In some embodiments, the third length D3 may be about 10 to 20 μm. The encapsulator 67 maybe disposed on the first high thermal conductivity layer 58. In some embodiments, the encapsulator 67 mayinclude an epoxy molding compound. The encapsulator 67 maycontact the upper surface of the first high thermal conductivity layer 58 and a portion of the side surfaces of the first semiconductor chip 40.

In some embodiments, side surfaces of the wiring structure 10, the first high thermal conductivity layer 58 and the encapsulator 67 maybe substantially coplanar. For example, side surfaces of the first scribe lane SL1, the first high thermal conductivity layer 58, and the encapsulator 67 maybe vertically aligned. The side surfaces of the first scribe lane SL1, the first high thermal conductivity layer 58, and the encapsulator 67 maybe substantially coplanar. Side surfaces of the second scribe lane SL2, the first high thermal conductivity layer 58, and the encapsulator 67 maybe vertically aligned. The side surfaces of the second scribe lane SL2, the first high thermal conductivity layer 58, and the encapsulator 67 maybe substantially coplanar. The side surfaces of the wiring structure 10, the first high thermal conductivity layer 58, and the encapsulator 67 maybe exposed.

The plurality of first through electrodes 13, the plurality of first internal terminals 53, and/or the plurality of external terminals 63 maybe utilized in the driving of the wiring structure 10 and/or the first semiconductor chip 40. For example, plurality of first through electrodes 13, the plurality of first internal terminals 53, and/or the plurality of external terminals 63 mayassist in signal transmission, power supply, and/or grounding. The at least one first heat dispersion through electrode 14, the plurality of first internal heat dispersion terminals 54 and the at least one external heat dispersion terminal 64 maydisperse and/or externally dissipate heat generated from the wiring structure 10 and the first semiconductor chip 40.

The first high thermal conductivity layer 58 maydirectly contact the wiring structure 10, the first semiconductor chip 40, the plurality of first internal terminals 53 and the plurality of first internal heat dispersion terminals 54. The first high thermal conductivity layer 58 maydisperse and externally dissipate heat generated from the wiring structure 10 and the first semiconductor chip 40.

Referring to FIGS. 2 to 4, the upper surface of the first high thermal conductivity layer 58 and the contact surface of the encapsulator 67 mayhave various profiles. For example, the profile of the upper surface of the first high thermal conductivity layer 58 maybe based on of the flowability and formation method of the first high thermal conductivity layer 58. The upper surface of the first high thermal conductivity layer 58 mayinclude an inclined surface. In some embodiments, the upper surface of the first high thermal conductivity layer 58 mayinclude a level gradually lowering with increasing distance from the first semiconductor chip 40.

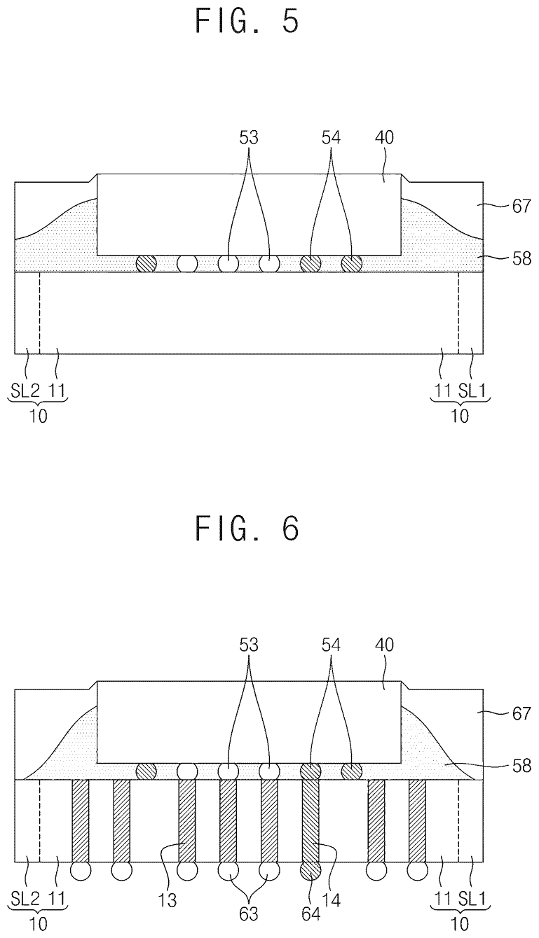

Referring to FIG. 5, the plurality of external terminals (“63” in FIG. 1) and the at least one external heat dispersion terminal (“64” in FIG. 1) may be omitted. In some embodiments, the wiring structure 10 mayinclude a printed circuit board, an interposer substrate, the semiconductor chip, and/or a combination thereof. For example, the wiring structure 10 mayinclude a package substrate and/or a printed circuit board (such as a main board). In some embodiments, the plurality of first through electrodes (“13” in FIG. 1) and the at least one first heat dispersion through electrode (“14” in FIG. 1) may be omitted. In some embodiments, a plurality of horizontal wirings (not shown) and a plurality of vertical wirings (not shown) may be disposed in the active region 11.

Referring to FIG. 6, a first high thermal conductivity layer 58 maybe between an active region 11 and a first semiconductor chip 40, and may extend on a plurality of scribe lanes SL1 and SL2. The first high thermal conductivity layer 58 maydirectly contact upper surfaces of a first scribe lane SL1 and a second scribe lane SL2. An encapsulator 67 maycover the first high thermal conductivity layer 58 and a wiring structure 10. The encapsulator 67 maydirectly contact the upper surfaces of the first scribe lane SL1 and the second scribe lane SL2. The encapsulator 67 mayin some embodiments, completely encapsulate the first high thermal conductivity layer 58.

Side surfaces of the wiring structure 10 and the encapsulator 67 maybe substantially coplanar. Side surfaces of the first scribe lane SL1 and the encapsulator 67 maybe vertically aligned. The side surfaces of the first scribe lane SL1 and the encapsulator 67 maybe substantially coplanar. Side surfaces of the second scribe lane SL2 and the encapsulator 67 maybe vertically aligned. The side surfaces of the second scribe lane SL2 and the encapsulator 67 maybe substantially coplanar.

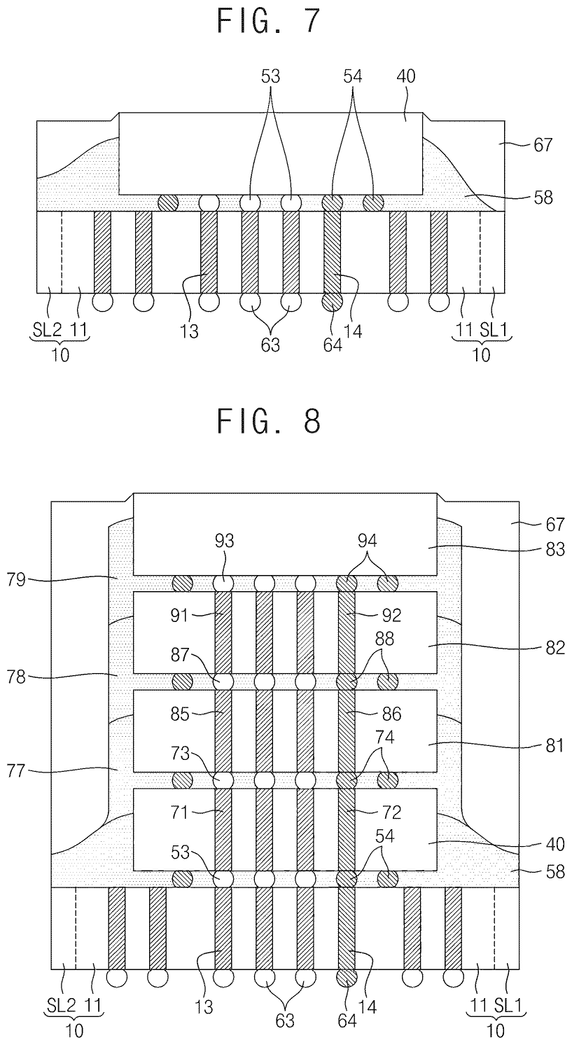

Referring to FIG. 7, a first high thermal conductivity layer 58 maybe between an active region 11 and a first semiconductor chip 40, may cover an upper surface of a second scribe lane SL2, and may partially cover an upper surface of a first scribe lane SL1. The first high thermal conductivity layer 58 maydirectly contact the upper surface of the first scribe lane SL1.

Side surfaces of the first scribe lane SL1 and the encapsulator 67 maybe vertically aligned. The side surfaces of the first scribe lane SL1 and the encapsulator 67 maybe substantially coplanar. Side surfaces of the second scribe lane SL2, the first high thermal conductivity layer 58, and the encapsulator 67 maybe vertically aligned. The side surfaces of the second scribe lane SL2, the first high thermal conductivity layer 58, and the encapsulator 67 maybe substantially coplanar.

Referring to FIG. 8, a semiconductor package according to some embodiments may include a wiring structure 10, a first semiconductor chip 40, a plurality of first internal terminals 53, a plurality of first internal heat dispersion terminals 54, a first high thermal conductivity layer 58, a second semiconductor chip 81, a plurality of second internal terminals 73, a plurality of second internal heat dispersion terminals 74, a second high thermal conductivity layer 77, a third semiconductor chip 82, a plurality of third internal terminals 87, a plurality of third internal heat dispersion terminals 88, a third high thermal conductivity layer 78, a fourth semiconductor chip 83, a plurality of fourth internal terminals 93, a plurality of fourth internal heat dispersion terminals 94, a fourth high thermal conductivity layer 79, a plurality of external terminals 63, at least one external heat dispersion terminal 64, and an encapsulator 67. Though illustrated as including four semiconductor chips 40, 81, 92, and 83, the semiconductor package is not so limited, and may include, for example, more than or less than the illustrated four semiconductor chips.

In some embodiments, each of the first semiconductor chip 40, the second semiconductor chip 81, the third semiconductor chip 82 and/or the fourth semiconductor chip 83 mayinclude a memory chip, a logic chip, a buffer chip, a controller chip, an application processor chip, an interposer chip, and/or a combination thereof. For example, each of the first semiconductor chip 40, the second semiconductor chip 81, the third semiconductor chip 82 and the fourth semiconductor chip 83 mayinclude the memory chip such as a volatile memory chip, a non-volatile memory chip, and/or a combination thereof. In some embodiments each of the first semiconductor chip 40, the second semiconductor chip 81, the third semiconductor chip 82 and/or the fourth semiconductor chip may include similar and/or different chips.

The first semiconductor 40 mayinclude a plurality of second through electrodes 71 and at least one second heat dispersion through electrode 72, which extend through the first semiconductor chip 40. The second semiconductor chip 81 mayinclude a plurality of third through electrodes 85 and at least one third heat dispersion through electrode 86, which extend through the second semiconductor chip 81. The third semiconductor ship 91 mayinclude plurality of fourth through electrodes 91 and at least one fourth heat dispersion through electrode 92, which extend through the third semiconductor chip 82.

The plurality of second internal terminals 73, the plurality of third internal terminals 87 and/or the plurality of fourth internal terminals 93 mayinclude a configuration similar to that of the plurality of first internal terminals 53. The plurality of second internal heat dispersion terminals 74, the plurality of third internal heat dispersion terminals 88 and/or the plurality of fourth internal heat dispersion terminals 94 mayinclude a configuration similar to that of the plurality of first internal heat dispersion terminals 54.

The plurality of second through electrodes 71, the plurality of third through electrodes 85 and the plurality of fourth through electrodes 91 mayinclude a configuration similar to that of the plurality of first through electrodes 13. The at least one second heat dispersion through electrode 72, the at least one third heat dispersion through electrode 86 and the at least one fourth heat dispersion through electrode 92 mayinclude a configuration similar to that of the at least one first heat dispersion through electrode 14.

Each of the second high thermal conductivity layer 77, the third high thermal conductivity layer 78, and the fourth high thermal conductivity layer 79 may include a configuration similar to that of the first high thermal conductivity layer 58. The second high thermal conductivity layer 77 maybe between the first semiconductor chip 40 and the second semiconductor chip 81, and/or may extend on side surfaces of the first semiconductor chip 40 and the second semiconductor chip 81. The second high thermal conductivity layer 77 maydirectly contact the side surfaces of the first semiconductor chip 40 and the second semiconductor chip 81. The second high thermal conductivity layer 77 maydirectly contact an upper surface of the first high thermal conductivity layer 58.

The third high thermal conductivity layer 78 maybe between the second semiconductor chip 81 and the third semiconductor chip 82, and/or may extend on side surfaces of the second semiconductor chip 81 and the third semiconductor chip 82. The third high thermal conductivity layer 78 maydirectly contact the side surfaces of the second semiconductor chip 81 and the third semiconductor chip 82. The third high thermal conductivity layer 78 maydirectly contact an upper surface of the second high thermal conductivity layer 77.

The fourth high thermal conductivity layer 79 maybe between the third semiconductor chip 82 and the fourth semiconductor chip 83, and/or may extend on side surfaces of the third semiconductor chip 82 and the fourth semiconductor chip 83. The fourth high thermal conductivity layer 79 maydirectly contact the side surfaces of the third semiconductor chip 82 and the fourth semiconductor chip 83. The fourth high thermal conductivity layer 79 maydirectly contact an upper surface of the third high thermal conductivity layer 78.

The encapsulator 67 maycover the first high thermal conductivity layer 58, the second high thermal conductivity layer 77, the third high thermal conductivity layer 78, and/or the fourth high thermal conductivity layer 79. The encapsulator 67 maydirect contact side surfaces of the fourth semiconductor chip 83. Though the encapsulator 67 is illustrated as completely encapsulating each of the second high thermal conductivity layer 77, the third high thermal conductivity layer 78, and the fourth high thermal conductivity layer 79, the semiconductor package is not so limited.

The plurality of first internal heat dispersion terminals 54, the plurality of second internal heat dispersion terminals 74, the plurality of third internal heat dispersion terminals 88, the plurality of fourth internal heat dispersion terminals 94, the at least one external heat dispersion terminal 64, the at least one first heat dispersion through electrode 14, the at least one second heat dispersion through electrode 72, the at least one third heat dispersion through electrode 86, and/or the at least one fourth heat dispersion through electrode 92 maydisperse and/or externally dissipate heat generated from the wiring structure 10, the first semiconductor chip 40, the second semiconductor chip 81, the third semiconductor chip 82, and/or the fourth semiconductor chip 83. The first high thermal conductivity layer 58, the second high thermal conductivity layer 77, the third high thermal conductivity layer 78, and the fourth high thermal conductivity layer 79 maydisperse and/or externally dissipate heat generated from the wiring structure 10, the first semiconductor chip 40, the second semiconductor chip 81, the third semiconductor chip 82, and the fourth semiconductor chip 83.

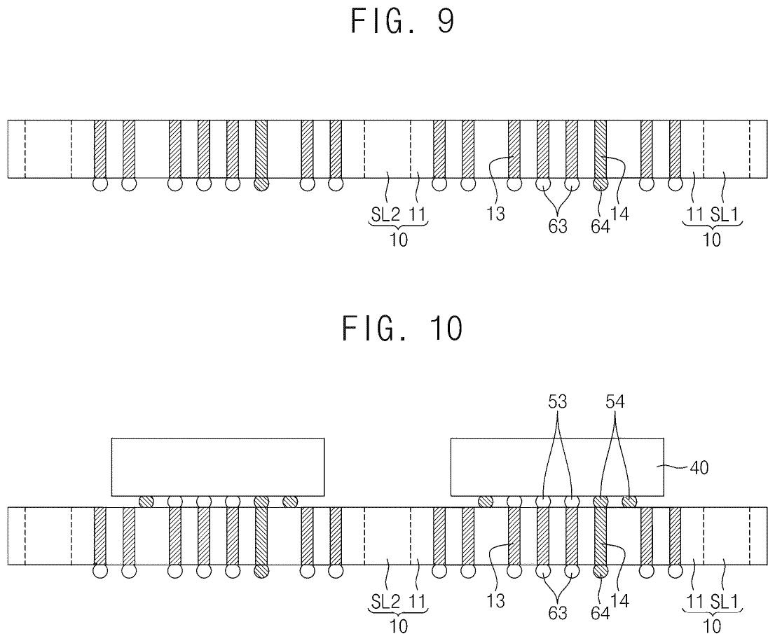

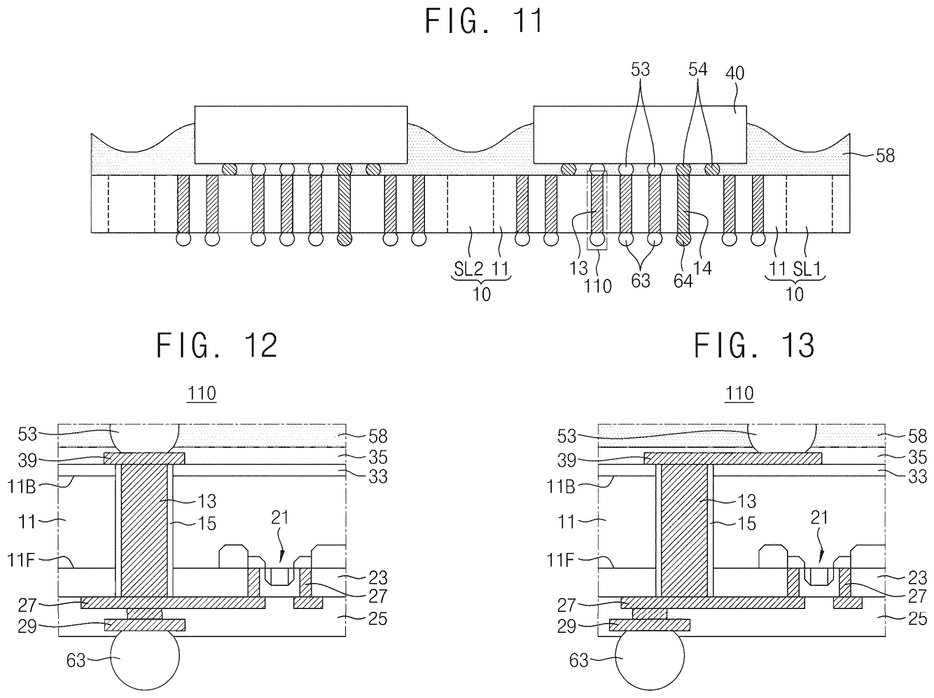

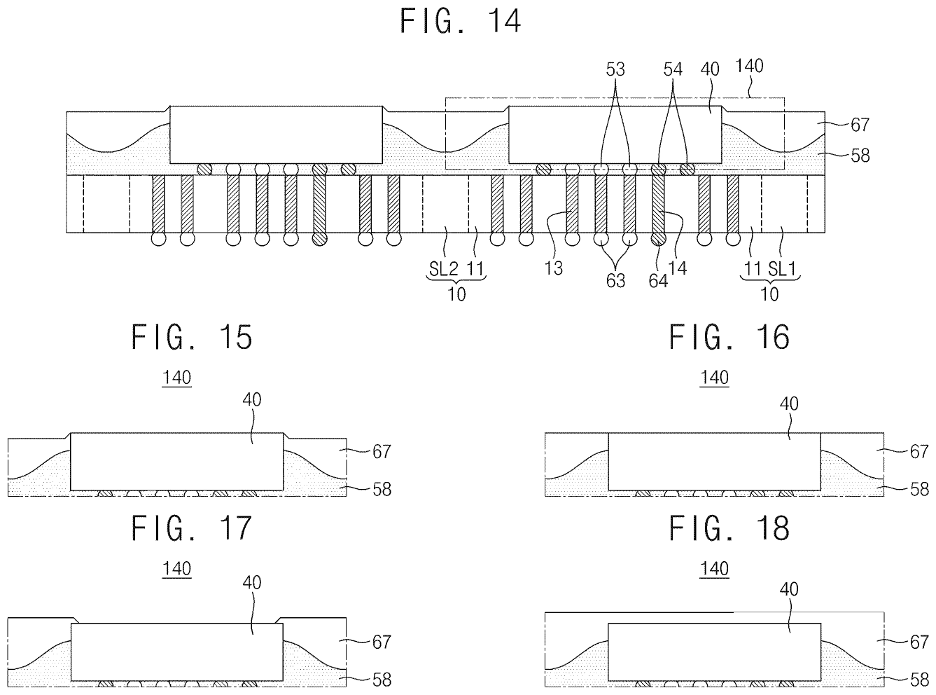

FIGS. 9, 10, 11, 14 and 19 are sectional views of a formation method for a semiconductor package according to some embodiments of the disclosure. FIGS. 12 and 13 are views showing a portion 110 of FIG. 11. FIGS. 15 to 18 are views showing a portion 140 of FIG. 14.

Referring to FIG. 9, a substrate including a plurality of wiring structures 10 having a plurality of scribe lanes SL1 and SL2, which are in continuity with side surfaces of the active regions 11, may be provided. A plurality of first through electrodes 13 and at least one first heat dispersion through electrode 14, which extend through the active region 11, may be formed in the substrate.

A plurality of external terminals 63 and at least one external heat dispersion terminal 64 maybe formed on a lower surface of the active region 11. Each of the plurality of external terminals 63 maybe electrically connected to a corresponding one of the plurality of first through electrodes 13. The at least one external heat dispersion terminal 64 maybe electrically connected to the at least one first heat dispersion through electrode 14.

Referring to FIG. 10, a plurality of first semiconductor chip 40 maybe mounted on the plurality of wiring structures 10. A plurality of first internal terminals 53 and a plurality of first internal heat dispersion terminals 54 maybe formed between the plurality of first semiconductor chips 40 and the plurality of wiring structures 10. The plurality of first internal terminals 53 and the plurality of first internal heat dispersion terminals 54 maycontact corresponding ones of the wiring structures 10 and the first semiconductor chips 40. In some embodiments, the formation of the plurality of first internal terminals 53 and the plurality of first internal heat dispersion terminals 54 mayinclude a thermocompression bonding process.

Referring to FIG. 11, a first high thermal conductivity layer 58 maybe formed on the plurality of wiring structures 10. The first high thermal conductivity layer 58 mayfill a space between the plurality of wiring structures 10 and the plurality of first semiconductor chips 40, and may extend on side surfaces of the plurality of first semiconductor chips 40. In some embodiments, the first high thermal conductivity layer 58 mayinclude a resin with a high degree of wetting and/or adhesion with the outer surface of the first semiconductor chip 40 when in a liquid phase. The first high thermal conductivity layer 58 maycompletely cover the plurality of scribe -lanes SL1 and SL2. An upper surface of the first high thermal conductivity layer 58 mayhave various profiles on the basis of the flowability and formation method of the first high thermal conductivity layer 58.

Referring to FIG. 12, the active region 11 mayinclude a first surface 11F, and a second surface 11B opposite to the first surface 11F. The first surface 11F may correspond to a front (e.g., bottom) surface, and the second surface 11B may correspond to a back (e.g., top) surface. A first insulating layer 23 and a second insulating layer 25 maybe sequentially stacked on the first surface 11F. Various kinds of active elements (such as a transistor 21) may be formed adjacent to and/or in the first surface 11F.

In some embodiments, the transistor 21 maybe formed in an interior of the active region 11 and/or in the first insulating layer 23. The transistor 21 mayinclude a fin field effect transistor (finFET), a multi-bridge channel transistor (MBCT) (such as MBCFET®), a nano-wire transistor, a vertical transistor, a recess channel transistor, a 3-D transistor, a planar transistor, and/or a combination thereof.

A third insulating layer 33 and a fourth insulating layer 35 maybe sequentially stacked on the second surface 11B. The first high thermal conductivity layer 58 maybe formed on the fourth insulating layer 35. A first through electrode 13, which extends through the active region 11, the first insulating layer 23, and the third insulating layer 33, may be formed. An insulating spacer 15 surrounding a side surface of the first through electrode 13 maybe formed.

A plurality of internal wirings 27 and at least one first pad 29 maybe formed in the first insulating layer 23 and/or the second insulating layer 25. The plurality of internal wirings 27 mayinclude a plurality of horizontal wirings and a plurality of vertical wirings. An external terminal 63 maybe formed on the second insulating layer 25. The external terminal 63 mayextend into the second insulating layer 25 such that the external terminal 63 contacts the first pad 29. Some of the plurality of internal wirings 27 maybe connected to the first pad 29 and the first through electrode 13. Some of the plurality of internal wirings 27 maybe connected to the transistor 21.

A second pad 39 maybe formed in the fourth insulating layer 35. The second pad 39 maybe connected to the first through electrode 13. A first internal terminal 53 maybe formed on the fourth insulating layer 35. The first internal terminal 53 mayextend through the first high thermal conductivity layer 58 and the fourth insulating layer 35 such that the first internal terminal 53 contacts the second pad 39.

The external terminal 63 maybe connected to the first internal terminal 53 via the first pad 29, the plurality of internal wirings 27, the first through electrode 13, and the second pad 39. The external terminal 63 maybe connected to the transistor 21 via the first pad 29 and the plurality of internal wirings 27. In some embodiments, the external terminal 63, the first through electrode 13, and the first internal terminal 53 maybe vertically aligned.

Each of the first through electrode 13, the plurality of internal wirings 27, the first pad 29, and the second pad 39 mayinclude a single layer and/or multiple layers. Each of the first through electrode 13, the plurality of internal wirings 27, the first pad 29 and the second pad 39 mayinclude a conductive material such as a metal (e.g., Cu, W, Ni, Co, Al, Ti, Ta, Ag, Pt, Au, Ru, Cr, Sn, and/or a combination thereof); a conductive oxide; a conductive nitride (e.g., WN, TiN, TaN, and/or a combination thereof); and/or a combination thereof.

Each of the insulating spacer 15, the first insulating layer 23, the second insulating layer 25, the third insulating layer 33, and the fourth insulating layer 35 mayinclude a single layer and/or multiple layers. Each of the insulating spacer 15, the first insulating layer 23, the second insulating layer 25, the third insulating layer 33, and the fourth insulating layer 35 mayinclude an insulating material such as silicon oxide, silicon nitride, silicon oxynitride, low-K dielectrics, high-K dielectrics, and/or a combination thereof.

Referring to FIG. 13, at least one of the external terminal 63 and the first internal terminal 53 maybe misaligned from the first through electrode 13. For example, straight lines perpendicular to the first surface 11F (e.g., while passing through centers of the external terminal 63, the first through electrode 13 and the first internal terminal 53, respectively) may extend in parallel.

Referring to FIG. 14, an encapsulator 67 maybe formed on the first high thermal conductivity layer 58. The encapsulator 67 mayinclude an epoxy molding compound. The encapsulator 67 maycontact side surfaces of the plurality of first semiconductor chips 40.

Referring to FIG. 15, an upper surface of the encapsulator 67 maybe formed at a level equal to or lower than an upper surface of the first semiconductor chip 40. The upper surface of the first semiconductor chip 40 maybe exposed.

Referring to FIG. 16, the upper surface of the encapsulator 67 maybe formed at substantially the same level as the upper surface of the first semiconductor chip 40. The upper surfaces of the encapsulator 67 and the first semiconductor chip 40 maybe exposed at substantially the same level.

Referring to FIG. 17, the upper surface of the encapsulator 67 maybe formed at a higher level than the upper surface of the first semiconductor chip 40.

Referring to FIG. 18, the encapsulator 67 maybe formed to completely cover upper surfaces of the first semiconductor chip 40 and the first high thermal conductivity layer 58.

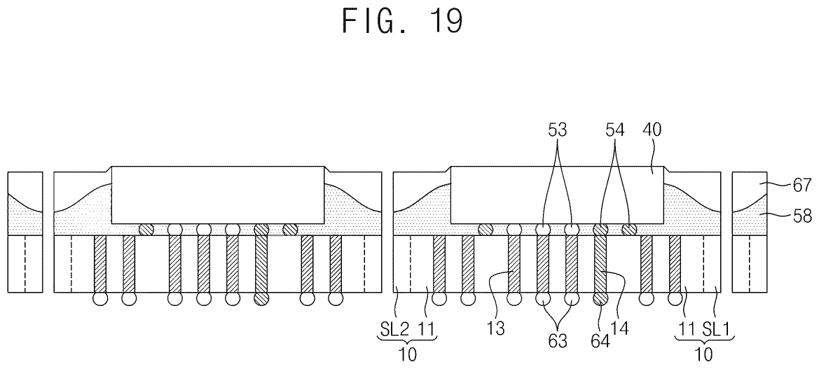

Referring to FIG. 19, the plurality of scribe lanes SL1 and SL2 may be cut using a sawing process.

In accordance with some example embodiments of the disclosure, a high thermal conductivity layer, which includes a portion between a wiring structure and a semiconductor chip and extends on a scribe lane of the wiring structure, is provided. The high thermal conductivity layer may be configured to disperse and externally dissipate heat generated from the wiring structure and the semiconductor chip. Thus, a semiconductor package having efficient heat dissipation characteristics may be realized.

While the embodiments of the disclosure have been described with reference to the accompanying drawings, it should be understood by those skilled in the art that various modifications may be made without departing from the scope of the disclosure and without changing essential features thereof. Therefore, the above-described embodiments should be considered in a descriptive sense only and not for purposes of limitation.

What is claimed is:

1. A semiconductor package comprising:
a wiring structure;
a semiconductor chip on the wiring structure;
a plurality of internal terminals between the wiring structure and the semiconductor chip, each of the plurality of internal terminals configured to provide at least one of a signal transmission, power supply, or grounding for the semiconductor chip;
a plurality of internal heat dispersion terminals between the wiring structure and the semiconductor chip, each of the plurality of internal heat dispersion terminals configured to disperse heat generated by the wiring structure and the semiconductor chip;
a high thermal conductivity layer between the wiring structure and the semiconductor chip; and
an encapsulator on the high thermal conductivity layer and contacting the semiconductor chip,
wherein sidewalls of at least the wiring structure and the encapsulator are substantially coplanar.

2. The semiconductor package of claim 1, wherein an upper surface of the encapsulator includes a flat portion substantially parallel to the upper surface of the wiring structure and an inclined portion between the flat portion and the semiconductor chip.

3. The semiconductor package of claim 1, wherein the plurality of internal heat dispersion terminals extend through the high thermal conductivity layer.

4. The semiconductor package of claim 1, wherein the plurality of internal heat dispersion terminals are configured not to provide at least one of a signal transmission, power supply, or grounding for the semiconductor chip.

5. The semiconductor package of claim 1, wherein each of the plurality of internal heat dispersion terminals includes the same material as the plurality of internal terminals.

6. The semiconductor package of claim 1, wherein the plurality of internal heat dispersion terminals are spaced apart from the plurality of internal terminals.

7. The semiconductor package of claim 1, wherein each of the plurality of internal heat dispersion terminals has the same size as the plurality of internal terminals.

8. The semiconductor package of claim 1, further comprising:
a plurality of through electrodes extending through the wiring structure and connected to the plurality of internal terminals; and
a plurality of heat dispersion through electrodes extending through the wiring structure and connected to the plurality of internal heat dispersion terminals.

9. The semiconductor package of claim 8, at least one of the plurality of internal heat dispersion terminals are not connected to both the plurality of through electrodes and the plurality of heat dispersion through electrodes.

10. The semiconductor package of claim 8, further comprising:
a plurality of external terminals on a lower surface of the wiring structure and connected to the plurality of through electrodes.

11. The semiconductor package of claim 10, further comprising a plurality of external heat dispersion terminals on the lower surface of the wiring structure and connected to the plurality of heat dispersion through electrodes.

12. The semiconductor package of claim 11, wherein each of the plurality of external heat dispersion terminals includes the same material as the plurality of external terminals.

13. The semiconductor package of claim 11, wherein each of the plurality of external heat dispersion terminals has the same size as the plurality of external terminals.

14. The semiconductor package of claim 1, wherein the high thermal conductivity layer fills a space between the plurality of internal terminals and the plurality of internal heat dispersion terminals.

15. A semiconductor package comprising:
a wiring structure;
a first semiconductor chip on the wiring structure;
a plurality of first internal terminals between the wiring structure and the first semiconductor chip, each of the plurality of first internal terminals configured to provide at least one of a signal transmission, power supply, or grounding for the first semiconductor chip;
a plurality of first internal heat dispersion terminals between the wiring structure and the first semiconductor chip, each of the plurality of first internal heat dispersion terminals configured to disperse heat generated by the wiring structure and the first semiconductor chip and not to provide at least one of a signal transmission, power supply, or grounding for the first semiconductor chip;
a second semiconductor chip on the first semiconductor chip;
a plurality of second internal terminals between the first semiconductor chip and the second semiconductor chip, a first high thermal conductivity layer between the wiring structure and the first semiconductor chip; and
an encapsulator on the first high thermal conductivity layer,
wherein sidewalls of at least the wiring structure and the encapsulator are substantially coplanar and
wherein the first high thermal conductivity layer covers an upper surface of the wiring structure and side surfaces of the first semiconductor chip.

16. The semiconductor package of claim 15, further comprising:
a plurality of first through electrodes extending through the wiring structure and connected to the plurality of first internal terminals; and
wherein the first semiconductor chip includes a plurality of second through electrodes extending through the first semiconductor chip and connected to the plurality of first internal terminals.

17. The semiconductor package of claim 16, wherein the plurality of second internal terminals are connected to the plurality of second through electrodes.

18. The semiconductor package of claim 16, further comprising:
a plurality of first heat dispersion through electrodes extending through the wiring structure and connected to the plurality of first internal heat dispersion terminals; and
wherein the first semiconductor chip includes a plurality of second heat dispersion through electrodes extending through the first semiconductor chip and connected to the plurality of first internal heat dispersion terminals.

19. The semiconductor package of claim 18, further comprising a plurality of second internal heat dispersion terminals between the first semiconductor chip and the second semiconductor chip,
wherein the plurality of second internal heat dispersion terminals are connected to the plurality of second heat dispersion through electrodes and spaced apart from the plurality of second internal terminals.

20. The semiconductor package of claim 15, further comprising a second high thermal conductivity layer between the first semiconductor chip and the second semiconductor chip,
wherein the first semiconductor chip is surrounded by the first high thermal conductivity layer and the second high thermal conductivity layer, and
wherein the encapsulator is on the second high thermal conductivity layer and spaced apart from the first semiconductor chip.
